(19) United States
(12) Patent Application Publication
(10) Pub. No.: US 2003/0198032 A1
(43) Pub. Date: Oct. 23, 2003

(54) Integrated circuit assembly and method for making same

(76) Inventors: Paul Collander, Espoo (FI); Petri Nyberg, Helsinki (FI); Vesa Korhonen, Helsinki (FI); Olli Pekka Koistinen, Masala (FI); Kari Koivunen, Espoo (FI)

Correspondence Address: PILLSBURY WINTHROP, LLP, P.O. BOX 10500, MCLEAN, VA, 22102, US

(21) Appl. No.: 10/127,685

(22) Filed: Apr. 23, 2002

(51) Int. Cl. H05K 7/06

(52) U.S. Cl. 361/760; 361/749; 361/750; 361/782; 257/724; 257/728; 361/780

(57) ABSTRACT

The invention relates to an integrated circuit assembly and a method of making same. The method according to the invention comprising providing a flex substrate having one or more dielectric tape layers, assembling one or more semiconductor chips to said flex substrate, said semiconductor chips having an active surface and a plurality of contact pads on said active surface, providing one or more conductive layers on said flex substrate, said conductive layers forming the electrical connections required for the assembly, electrically connecting the contact pads to the conductive layers.

### FIELD OF THE INVENTION

The invention relates to electronic circuits, and especially to an assembly of multi-chip circuits operating on microwave, millimeter wave or radio frequency ranges, which assembly is based on a multi-layer flex substrate.

### BACKGROUND OF THE INVENTION

Monolithic microwave integrated circuits (MMIC) are used in microelectronics at high frequency ranges. During assembly, individual semiconductor chips are typically connected to a base structure, i.e. substrate, which is in turn connected to a circuit panel, such as printed circuit board (PCB). In multi-chip modules, several unpackaged semiconductor chips are placed on one substrate. The substrate is then connected to a common circuit panel and enclosed in a common package. This saves space that would be wasted when using individually packaged semiconductor chips. A multi-chip module (MCM) is usually an assembly made of a rigid material, such as ceramic or other material, which comprises a ceramic substrate and several semiconductor chips on the substrate and in which the connections between the semiconductor chips are implemented by multi-layer circuitries insulated from each other by insulating layers and connected to each other by lead-throughs. In conventional multi-chip assemblies, the adjacent chips are placed on the surface of the substrate by means of a planar technique, and non-planar solutions are impossible.

One reason for the poor microwave performance in conventional assemblies of monolithic microwave integrated circuits comprising ceramic substrates is the connections between the chip surface and the conductive patterns in the different layers of the multi-layer circuit panel. The insertion loss of a coaxial line or stripline on top of the inter-layer connections increases at high frequencies, which in turn causes a weakening in the signal strength. One of the biggest problems in MMIC assemblies comprising ceramic substrates is also the incompatibility caused by the different thermal coefficients of expansion of the substrate and the semiconductor circuits.

### BRIEF DESCRIPTION OF THE INVENTION

It is thus an object of the invention to implement an integrated circuit assembly and a method for making one in such a manner that the above-mentioned problems are solved. This is achieved by a method of making an integrated circuit assembly, the method of the invention comprising providing a flex substrate having one or more dielectric layers, assembling one or more semiconductor chips to said flex substrate, said semiconductor chips having an active surface and a plurality of contact pads on said active surface, providing one or more conductive layers on said flex substrate, said conductive layers forming the electrical connections required for the assembly and electrically connecting the contact pads to the conductive layers.

The invention also relates to an integrated circuit assembly, the integrated circuit assembly of the invention comprising a flex substrate that comprises one or more dielectric tape layers, one or more semiconductor chips on said flex substrate, said semiconductor chips comprising an active surface having several contact pads, one or more conductive layers on said flex substrate, said conductive layers forming the electric connections required in the assembly, and means for connecting said contact pads directly to the conductive layer of the flex substrate.

Preferred embodiments of the invention are set forth in the dependent claims.

The assembly of the invention provides several advantages. One advantage of the invention is that it is possible to have very high component densities on assemblies operating at high frequency ranges. A further advantage is that inexpensive organic materials can be used as the substrates without the material selection impeding the operation of the assembly. The flex substrate used in the solution of the invention receives the stress caused by the different thermal coefficients of expansion of the materials, thus reducing the stress directed to the joint between the circuit and substrate and improving the reliability of the device and saving costs. A yet further advantage of the invention is that the assembly of the invention comprising a flex substrate is suited for use for three-dimensional, non-planar mounting of said components.

### BRIEF DESCRIPTION OF THE FIGURES

The invention will now be described in more detail using as examples the attached drawings showing the preferred embodiments of the invention, in which

FIG. 1 shows a top plan view of an assembly of the presented solution comprising flex substrate,

FIGS. 2A and 2B show a cross-profile of an embodiment of the presented solution,

FIG. 2C shows a top plan view of the embodiment of FIGS. 2A and 2B,

FIGS. 3A and 3B show a cross-profile of an embodiment of the presented solution,

FIG. 3C shows a top plan view of the embodiment of FIGS. 3A and 3B,

FIGS. 4A and 4B show a cross-profile of an embodiment of the presented solution,

FIG. 4C shows a top plan view of the embodiment of FIGS. 4A and 4B,

FIG. 5A shows a cross-profile of an embodiment of the presented solution,

FIG. 5B shows a top plan view of the embodiment of FIG. 5A.

### DETAILED DESCRIPTION OF THE INVENTION

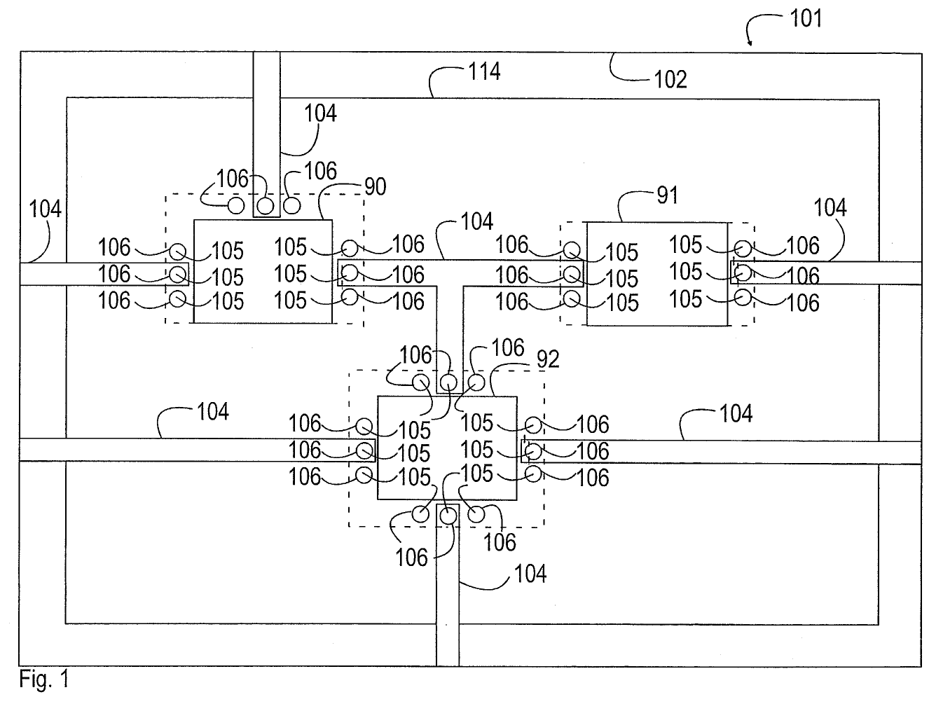

FIG. 1 shows a top view of an assembly 101 according to one embodiment of the presented solution. The assembly 101 comprises a flex substrate 102 that comprises one or more dielectric tape layers. In the embodiment of FIG. 1, said dielectric tape layers are made of a flexible, organic material, such as polyimide, LCP (Liquid Crystal Polymer) or other suitable flex substrates. Several electronic components, such as semiconductor chips 90, 91, 92, are connected to the flex substrate 102. On top of the flex substrate 102, there are conductive layers 104 made of an electrically conductive material, such as copper. Vias 106 are formed through the flex substrate layers 102, and at least some of the vias form an electrical contact between the semiconductor chips 90, 91, 92 and the conductive layers 104. The vias 106 are at least partly filled with a conductive material 105, such as metal. In FIG. 1, the locations of the vias 106 are marked, even though when seen from the top, at least a part of them remain under the conductive layers 104. Some of the conductive layers 104 run between vias 106 and some of them run from the vias 106 at the semiconductor chips 90, 91, 92 to the edge of the flex substrate 102. Thus, some of the conductive layers 104 form an electrical contact between one or more semiconductor chips 90, 91, 92, whereas some of them form an electrical contact from the semiconductor chips 90, 91, 92 to the edges of the flex substrate 102. The conductive layers 104 extending to the outer edges of the flex substrate 102 are used in connecting the assembly 101 electrically to a motherboard, for instance. The conductive layers 104 thus form the necessary electrical connections in the assembly. The conductive layers 104 can for instance form a microstrip, stripline or coplanar wave-guide configuration.

In FIG. 1 according to the embodiment of the presented solution the semiconductor chips 90, 91, 92 are also connected to a mechanical part 114, such as a mechanical base, a frame or a heatsink.

In FIG. 1, the visible part of the semiconductor chips 90 91, 92 is shown by a continuous line. The parts of the semiconductor chips 90, 91, 92 that remain under the flex substrate 102 in a top view of the assembly 101 and at which vias 106 are formed in the flex substrate 102, are marked with a dashed line.

The unpackaged semiconductor chips 90, 91, 92 can be electrically connected to the flex substrate 102 in several different ways. The semiconductor chips 90, 91, 92 can be connected in manners known per se, for instance by reflow soldering, microwelding, by using flip chip techniques or large BGA (ball grid array) balls.

The semiconductor chips 90, 91, 92 can, according to the presented solution, be microwave chips (MW), for instance. In addition to microwave chips, RF (radio frequency) and DC signals and a ground layer can be integrated to one and the same flex substrate 102.

Due to the flexible nature of the flex substrate 102, the flex substrate 102 according to one embodiment of the presented solution can receive mechanical stress in the semiconductor chip 90, 91, 92 interconnects. The assembly 101 can also be made three-dimensional depending on the requirements of each assembly, such as thermal solutions and in-out signaling.

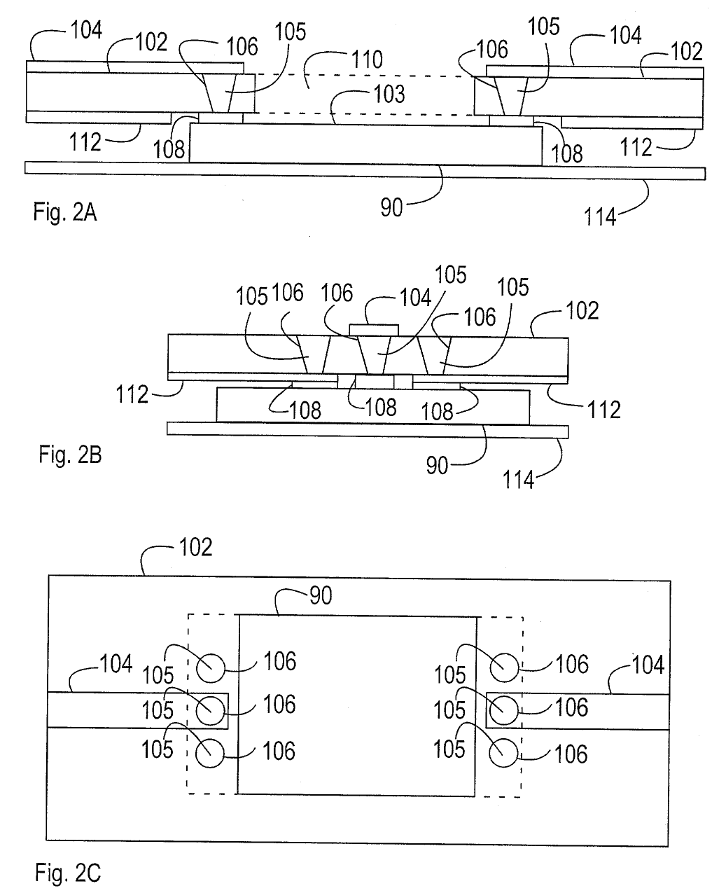

FIGS. 2A, 2B and 2C show one embodiment of the invention, in which the conductive layers 104 form a microstrip line configuration. Typically, a microstrip line is made up of a strip line and ground layer having a dielectric substrate between them. FIG. 2A shows an enlarged cross-profile of the embodiment of the presented solution. The active surface 103 of the semiconductor chip 90 has contact pads 108. Alternatively, the contact pads 108 can also be solder balls or bumps. Vias 106 are formed in the flex substrate 102, through which the semiconductor chip 90 is electrically connected directly to the conductive layers 104 on top of the vias 106. The conductive layers 104 are on top of the flex substrate 102 in such a manner that some of the conductive layers 104 come above the vias 106.

The flip chip technique used in electrically connecting the semiconductor chips 90, 91, 92 is a useful alternative in GaAs devices that operate at microwave and RF ranges. In the solder-bump flip chip technique, unpackaged semiconductor chips are directly connected to the flex substrate. A direct connection to the flex substrate is formed through contact bumps made on the active surface of the semiconductor chips. Due to the flexibility of the flex substrate, no underfill is needed. The bumpless universal contact unit (UCU) technique is another flip chip technique. No balls, contact bumps or underfill are needed in connections in the UCU technique. In the UCU technique, contact pads 108 are formed of aluminum or copper, for instance, on the active surface 103 of the semiconductor chips 90, 91, 92, and on top of the pads, electrical contacts are formed for instance by means of the conductive material 105 in the vias 106.

In the embodiment of FIG. 1, the semiconductor chip 90 is typically reflow soldered to the conductive material 105 in the vias 106 and the conductive layers 104. Instead of soldering, microwelding or UCU methods known per se can also be used.

In one embodiment of the invention, a space 110 free of the substrate material, such as an air window, is formed in the flex substrate 102 above the active surface 103 of the semiconductor chip 90. The purpose of the space 110 free of the substrate material is to minimize the effect of the flex substrate 102 on the performance of the semiconductor chip 90. The space 110 free of the substrate material is of equal height to one or more flex substrate layers in the presented solution. The height of the space 110 free of the substrate material can be adjusted as required to ensure that the operation of the semiconductor chip 90 is as trouble-free as possible.

The ground layer 112 is connected to the flex substrate 102 opposite the conductive layers 104 in such a manner that the flex substrate 102 is between the conductive layers 104 and the ground layer 112.

In FIGS. 2A and 2B according to one embodiment of the presented solution the semiconductor chip 90 is also connected to a mechanical part 114, such as a mechanical base, a frame or a heatsink.

FIG. 2B shows the embodiment of FIG. 2A from the side. The figure shows that some of the contact pads 108 are connected to the ground layers 112 below the flex substrate 102. FIG. 2C shows the embodiment of FIGS. 2A and 2B from the top. The part of the semiconductor chip 90 that is visible when seen from the top is marked with a continuous line, and a dashed line shows the part of the semiconductor chip 90 that remains below the flex substrate 102 when seen from the top. The conductive layers 104 run on top of the vias 106 at the location of the semiconductor chip 90 to the edges of the flex substrate 102.

As described in FIGS. 2A, 2B and 2C, the microwave performance of the assembly can be improved considerably by using air windows 110 next to the active surface 103 of the semiconductor chip 90.

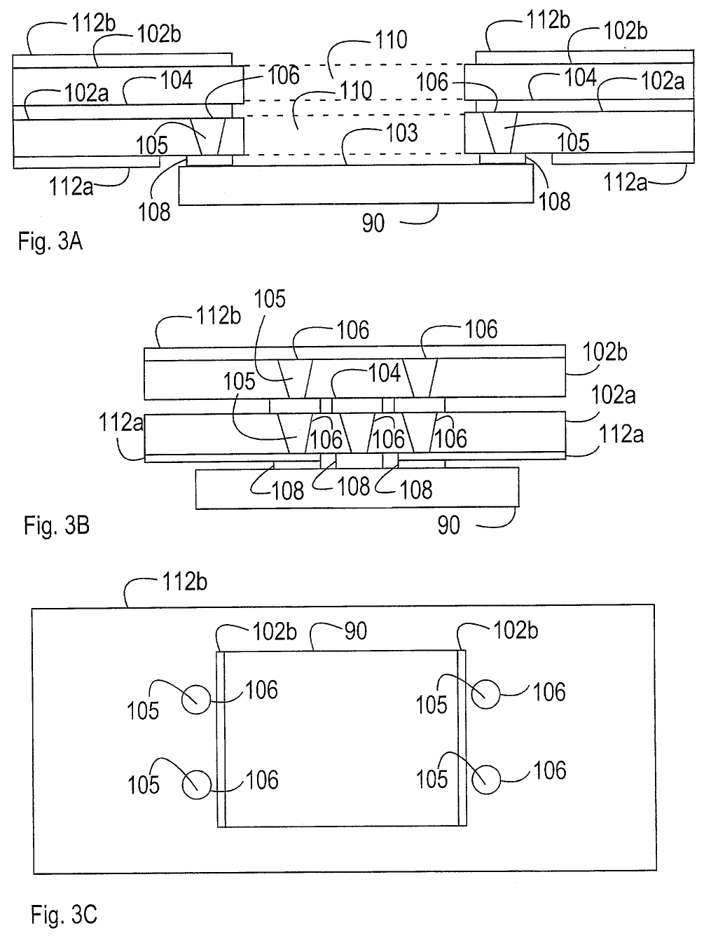

FIGS. 3A, 3B and 3C disclose a solution according to one embodiment of the invention, in which the conductive layers 104 form a stripline configuration. In a stripline configuration, the stripline is typically between two ground layers. In FIGS. 3A, 3B and 3C, the flex substrate comprises layers 102a and 102b. FIG. 3A is an enlarged cross-profile of the embodiment of the presented solution. The semiconductor chip 90 is reflow soldered to the conductive material 105 in the conductive vias 106 and to the conductive layers 104. Instead of reflow soldering, the semiconductor chip 90 can be electrically connected to the conductive layers 104 by brazing or by using flip chip techniques known per se.

Conductive vias 106 are formed in the lower flex substrate layer 102a above the active surface 103 of the semiconductor chip 90. The conductive layers 104 are above the conductive vias 106, and thus between the flex substrate layers 102a and 102b. The space 110 free of the flex substrate material, such as an air window, at the location of the active surface 103 of the semiconductor chip 90 is formed by making an opening through both flex substrate layers 102a and 102b or just through the flex substrate layer 102a. The upper ground-layer 112b is on top of the upper flex substrate layer 102b located above the conductive layers 104 and the lower ground-layer 112a is below the lower flex substrate layer 102a.

FIG. 3B shows the embodiment of FIG. 3A from one side. As can be seen in the figure, at least some of the contact pads 108 of the semiconductor chip 90 are electrically connected to the conductive layer 104 and some of the contact pads 108 are connected to the lower ground-layer 112a. The upper ground-layer 112b is electrically connected to the lower ground-layer 112a through the conductive vias 106 formed through the flex substrate layers 102a, 102b. FIG. 3C shows a top view of the embodiment of FIGS. 3A and 3B. The upper ground-layer 112b covers most of the figure. In a top view, a part of the active surface of the semiconductor chip 90 and a part of the upper flex substrate layer 102b are visible. The figure also shows the locations of the vias 106 formed through the upper flex substrate layer 102b, which remain under the upper ground-layer 112b.

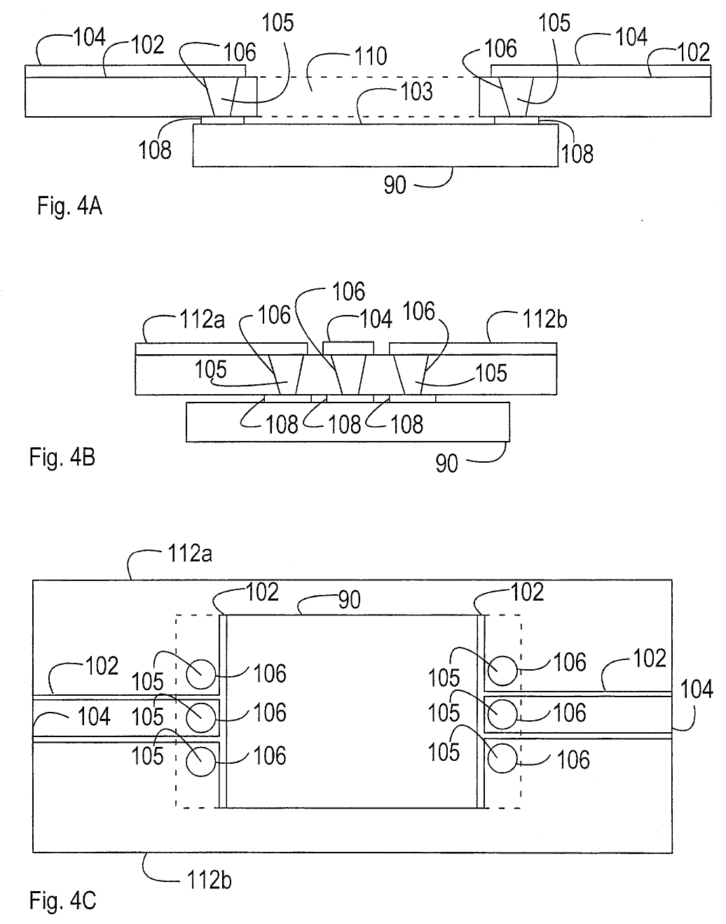

FIGS. 4A, 4B, 4C show a solution according to one embodiment of the invention, in which the conductive layers 104 form a coplanar transmission line, such as a coplanar waveguide line, configuration. In a coplanar line, there are typically ground layer halves on both sides of a stripline. FIG. 4A shows an enlarged cross-profile of the flex substrate 102. There are contact pads 108 on top of the active surface 103 of the semiconductor chip 90. The flex substrate 102 comprises conductive vias 106, through which the semiconductor chip 90 is electrically connected directly to the conductive layers 104 on top of the conductive vias 106. The semiconductor chip 90 is reflow soldered to the conductive material 105 in the conductive vias 106 and to the conductive layers 104. Instead of reflow soldering, the semiconductor chip 90 can be electrically connected to the conductive layers 104 by brazing or by using flip chip techniques known per se. The conductive layers 104 are on top of the flex substrate in such a manner that some of the conductive layers 104 are above the conductive vias 106. In a preferred embodiment of the invention, a space 110 free of the flex substrate material, such as an air window, is formed at the location of the active surface 103 of the semiconductor chip 90 in the flex substrate 102.

FIG. 4B shows the embodiment of FIG. 4A from one side. As can be seen in the figure, some of the contact pads 108 are connected to the ground layers 112a and 112b located on top of the flex substrate 102 through the conductive vias 106 formed through the flex substrate 102 in such a manner that the ground layers 112a and 112b are on both sides of the conductive layer 104. FIG. 4C shows a top view of the embodiment of FIGS. 4A and 4B. The section of the semiconductor chip 90 that is visible as seen from above is marked with a continuous line and the sections marked with a dashed line show the sections of the semiconductor chip 90 that remain under the ground layer 112 when seen from above. The ground layers 112a and 112b are on both sides of the conductive layers 104. The vias 106 formed through the flex substrate layer 102 remain under the ground layers 112a, 112b and the conductive layers 104 when seen from above. A part of the flex substrate layer 102 is visible when seen from above.

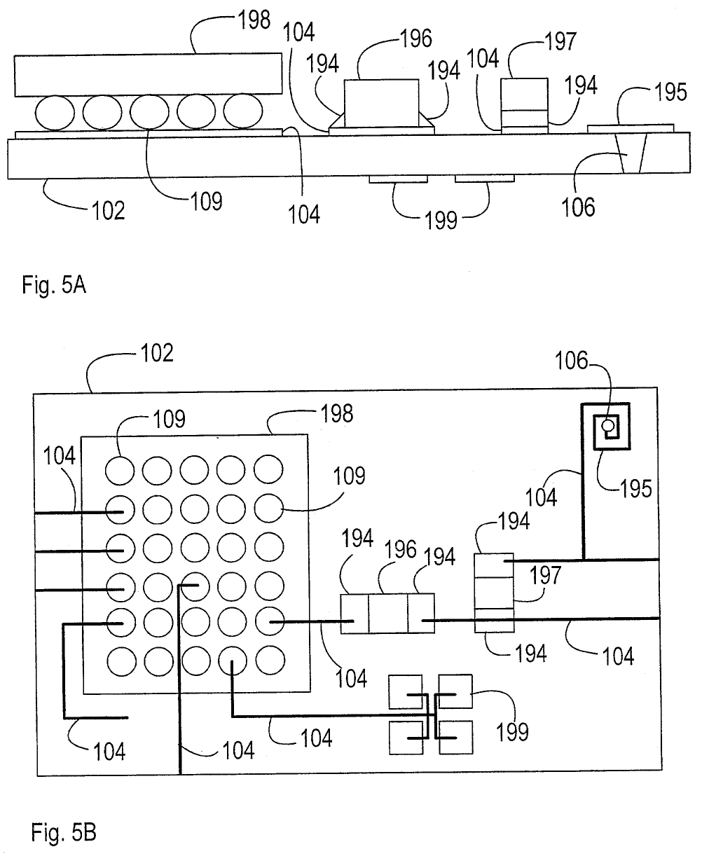

FIGS. 5A and 5B show one embodiment, in which the semiconductor chip is replaced by surface mount device (SMD) packages 196, 197, 198 which comprise a semiconductor chip or other components. In FIG. 5A, an active SMD package 198 is directly connected to the conductive layers 104 on top of the flex substrate 102 by means of large contact material components 109, such as pads, leads, BGA (Ball Grid Array) balls or similar. Alternatively a QFP (Quad Flat Package) package technique can be used. In FIG. 5A, two passive SMD packages 196, 197, such as chip capacitors, are also on top of the flex substrate 102. The two passive SMD packages 196, 197 in FIGS. 5A and 5B are identical, but in respect of each other they are positioned in different directions. The SMD packages 196, 197 are typically reflow soldered to the conductive layers 104. FIGS. 5A and 5B also show the solder joints 194 of the passive SMD packages 196, 197. For simplicity, not all the conductive layers and ground layers on top of the flex substrate 102 are shown in FIGS. 5A and 5B.

In FIGS. 5A and 5B a passive component 195 is integrated in the flex substrate 102. In FIGS. 5A and 5B the passive component 195 is a coil, made up from some of the conductive layers 104 on the flex substrate 102. It is also possible to integrate directly to the flex substrate 102 other passive components, such as capacitances, resistors, filters, and couplers, using metal tracks, dielectrics, vias, air, and other materials.

FIGS. 5A and 5B also show a patch matrix antenna 199 integrated to the flex substrate 102. In FIGS. 5A and 5B the patch matrix antenna 199 is on the other side of the flex substrate 102 than the SMD packages 196, 197, 108 and the passive component 195. The patch matrix antenna 199 is made up of some of the conductive layers 104 on the flex substrate 102.

FIG. 5B shows a top view of the embodiment of FIG. 5A. The locations of the BGA balls 109 of the active SMD package 198 are marked in FIG. 5B even though in reality they remain under the SMD package 198 when seen from above. In a top view, the location of the patch matrix antenna 199, which remains under the flex substrate 102, is also marked. The FIG. 5B also shows the passive SMD packages 196,197 and the passive component 195, such as a coil.

In FIG. 5B some of the conductive layers 104, forming for example metal tracks, on top of the flex substrate layer 102 run from the SMD packages 196, 197, 198 to the edges of the flex substrate 102 forming the required connections in the assembly. Some of the conductive layers 104 run from the active SMD package 198 to the solder joint 194 of the passive SMD package 196 and some to the patch matrix antenna 199 through the flex substrate 102. One of the conductive layers 104 also runs from one passive SMD package 196 to the other passive SMD package 197 and from there to the edge of the flex substrate 102. In FIG. 5B the spiral shaped coil 195 can be seen. The conductive layers 104 connect the coil 195 to the other passive SMD package 197 and to the edges of the flex substrate 102. The inner part 180 of the spiral shaped coil 195 is connected to the assembly for example by using a connective via 106.

In the embodiments according to FIGS. 5A and 5B both active and passive components are integrated to one flex substrate 102, whereby it is possible to have very high component densities on assemblies operating at high frequency ranges. The passive components, such as inductors or capacitors, to be integrated to the flex substrate 102 can be made up of conductive layers 104 and/or dielectric tape layers of the flex substrate 102. In addition, resistive layers or patches can also be added to form resistors, which passive components can comprise RF elements made without active components.

In the solutions according to the embodiments described above, patch-type and/or area-matrix-built-type antennas, for instance, can be integrated to one and the same flex substrate 102, where it is also possible to have for example spaces 110 free of the substrate material, such as air windows, to minimize the effect of the flex substrate 102 on the performance of the assembly.

In the solutions according to the embodiments described above, the flex substrate 102 forms a flexible protection for electric connections and receives the stress caused by the different thermal coefficients of expansion of the used materials, thus improving reliability and saving costs. Due to the flexibility of the flex substrate material 102, it can also be bent three-dimensionally around a bending point, and the components can also be located in arbitrary (3D) positions with respect to each other. Non-planar configurations are thus possible. By means of the presented solutions, it is possible to have very high component densities for microwave circuits.

Even though the invention has been explained in the above with reference to examples in accordance with the accompanying drawings, it is obvious that the invention is not restricted to them but can be modified in many ways within the scope of the inventive idea disclosed in the attached claims.

1. An integrated circuit assembly comprising:
a flex substrate that comprises one or more dielectric tape layers,
one or more semiconductor chips on said flex substrate, said semiconductor chips comprising an active surface having several contact pads,
one or more conductive layers on said flex substrate, said conductive layers forming the electric connections required in the assembly,
means for connecting said contact pads directly to the conductive layer of the flex substrate,
one or more passive components on said flex substrate, to which said semiconductor chips are connected.

2. An integrated circuit assembly comprising:
a flex substrate that comprises one or more dielectric tape layers,
one or more semiconductor chips on said flex substrate, said semiconductor chips comprising an active surface having several contact pads,
one or more conductive layers on said flex substrate, said conductive layers forming the electric connections required in the assembly,
means for connecting said contact pads directly to the conductive layer of the flex substrate.

3. The assembly as claimed in claim 2, wherein said assembly comprises one or more passive components on said flex substrate, to which said semiconductor chips are connected.

4. The assembly as claimed in claim 3, wherein said one or more passive components are inductors, capacitances, resistors, filters, couplers or other RF elements.

5. The assembly as claimed in claim 3, wherein said one or more passive components are in a surface mount package.

6. The assembly as claimed in claim 2, wherein said one or more conductive layers form a microstrip, a stripline or a Coplanar Waveguide line circuit configuration.

7. The assembly as claimed in claim 2, wherein said one or more semiconductor chips are radio frequency or microwave chips.

8. The assembly as claimed in claim 2, wherein said one or more semiconductor chips are in a surface mount package.

9. The assembly as claimed in claim 2, wherein one or more conductive vias are formed through said at least one dielectric tape layer of the flex substrate material and between said one or more contact pads on said semiconductor chip and one or more conductive layers forming bumpless flip chip connections.

10. The assembly as claimed in claim 2, wherein some of said one or more conductive layers form one or more ground layers.

11. The assembly as claimed in claim 2, wherein said one or more conductive layers form a patch antenna or an area matrix built antenna.

12. The assembly as claimed in claim 2, wherein said one or more semiconductor chips are connected to a mechanical part.

13. The assembly as claimed in claim 12, wherein said mechanical part is a mechanical base, a frame or a heatsink.

14. An integrated circuit assembly comprising:
a flex substrate that comprises one or more dielectric tape layers,
one or more semiconductor chips on said flex substrate, said semiconductor chips comprising an active surface having several contact pads,
one or more conductive layers on said flex substrate, said conductive layers forming the electric connections required in the assembly,
means for connecting said contact pads directly to the conductive layer of the flex substrate,
one or more spaces free of the substrate material at the location of the active surface of said one or more semiconductor chips through one or more dielectric tape layers of the flex substrate material forming a recessed area or air window.

15. The assembly as claimed in claim 14, wherein said assembly comprises one or more passive components on said flex substrate, to which said semiconductor chips are connected.

16. A method of making an integrated circuit assembly, comprising:
providing a flex substrate having one or more dielectric tape layers,
assembling one or more semiconductor chips to said flex substrate, said semiconductor chips having an active surface and a plurality of contact pads on said active surface,
providing one or more conductive layers on said flex substrate, said conductive layers forming the electrical connections required for the assembly,
electrically connecting the contact pads to the conductive layers,
assembling one or more passive components on said flex substrate, to which said semiconductor chips are connected.

17. A method of making an integrated circuit assembly, comprising:
providing a flex substrate having one or more dielectric tape layers,
assembling one or more semiconductor chips to said flex substrate, said semiconductor chips having an active surface and a plurality of contact pads on said active surface,
providing one or more conductive layers on said flex substrate, said conductive layers forming the electrical connections required for the assembly,
electrically connecting the contact pads to the conductive layers.

18. The method as claimed in claim 17, wherein one or more passive components are assembled on said flex substrate, to which said semiconductor chips are connected.

19. The method as claimed in claim 18, wherein one or more passive components are formed by said flex substrate and said conductive layers.

20. The method as claimed in claim 19, wherein said one or more passive components to be connected are inductors, capacitances, resistors, filters, couplers or other RF elements.

21. The method as claimed in claim 17, wherein one or more conductive layers are formed in such a manner that a microstrip, a stripline or a Coplanar Waveguide line circuit configuration is produced.

22. The method as claimed in claim 17, wherein said one or more semiconductor chips are microwave or radio frequency chips.

23. The method as claimed in claim 17, wherein said one or more semiconductor chips are connected in a surface mount package.

24. The method as claimed in claim 17, wherein one or more conductive vias are formed through said one or more dielectric tape layers of the flex substrate material and between said one or more contact pads on said semiconductor chips and one or more conductive layers forming bumpless flip chip connections.

25. The method as claimed in claim 17, wherein one or more ground layers are formed of said one or more conductive layers.

26. The method as claimed in claim 17, wherein said one or more conductive layers are formed in such a manner that a patch antenna or an area matrix built antenna is produced.

27. The method as claimed in claim 17, wherein said one or more semiconductor chips are connected to a mechanical part.

28. The method as claimed in claim 27, wherein said mechanical part is a mechanical base, a frame or a heatsink.

29. A method of making an integrated circuit assembly, comprising:
providing a flex substrate having one or more dielectric tape layers,
assembling one or more semiconductor chips to said flex substrate, said semiconductor chips having an active surface and a plurality of contact pads on said active surface,
providing one or more conductive layers on said flex substrate, said conductive layers forming the electrical connections required for the assembly,
electrically connecting the contact pads to the conductive layers,
forming one or more spaces free of the substrate material at the location of the active surface of said at least one semiconductor chip through at least one dielectric tape layer of the flex substrate material forming a recessed area or air window.

30. The method as claimed in claim 29, wherein one or more passive components are assembled on said flex substrate, to which said semiconductor chips are connected.
